(19) United States
(12) Patent Application Publication
(10) Pub. No.: US 2013/0300399 A1
(43) Pub. Date: Nov. 14, 2013

(54) SIGNAL SWITCHING DEVICE AND ELECTRONIC APPRATUS USING THE SAME

(71) Applicants: HONG FU JIN PRECISION INDUSTRY (SHENZHEN) CO., LTD., Shenzhen (CN); HON HAI PRECISION INDUSTRY CO., LTD., New Taipei (TW)

(72) Inventor: LU-QING MENG, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/726,257

(22) Filed: Dec. 24, 2012

(30) Foreign Application Priority Data
May 8, 2012 (CN) 201210139794.0

(51) Int. Cl. G01R 31/02

(52) U.S. Cl. CPC G01R 31/02
USPC 324/73.1

(57) ABSTRACT

A signal switching device connected between at least one electronic device and a testing device includes a switching module and a control unit connected to the switching module. Each electronic device is capable of outputting a first signal and a second signal. The switching module is connected to each electronic device. When the switching device is in a first state, the switching module receives the first signal, and the control unit controls the switching module to transmit the first signal to the testing device. When the switching module is in a second state, the switching module receives the second signal, and the control unit controls the switching module to transmit the second signal to the testing device.

### BACKGROUND

1. Technical Field

The present disclosure relates to signal switching devices; and more particularly, to a signal switching device and an electronic apparatus using the same.

2. Description of Related Art

Electronic devices, such as computers, digital versatile disc (DVD) players and the like, must be tested to check if each electronic device is defect free or defective. Generally, a plurality of electronic devices is connected to a testing device. A testing process for testing composite video broadcast signal and YPbPr signal output by the electronic devices is described as follows: when testing the composite video broadcast signal output by one electronic device, an operator controls the testing device to change to a first mode for testing the composite video broadcast signal; after testing the composite video broadcast signal of the electronic device, the operator controls the testing device to change to a second mode for testing the YPbPr signal of the electronic device. When testing a next electronic device, the operator should repeat the above testing process again. Therefore, the above testing process may be time consuming and complicated.

Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout two views.

FIG. 1 is a block diagram showing an electronic apparatus in accordance with one embodiment.

FIG. 2 is a circuit diagram of the electronic apparatus in FIG. 1 in accordance with one embodiment.

### DETAILED DESCRIPTION

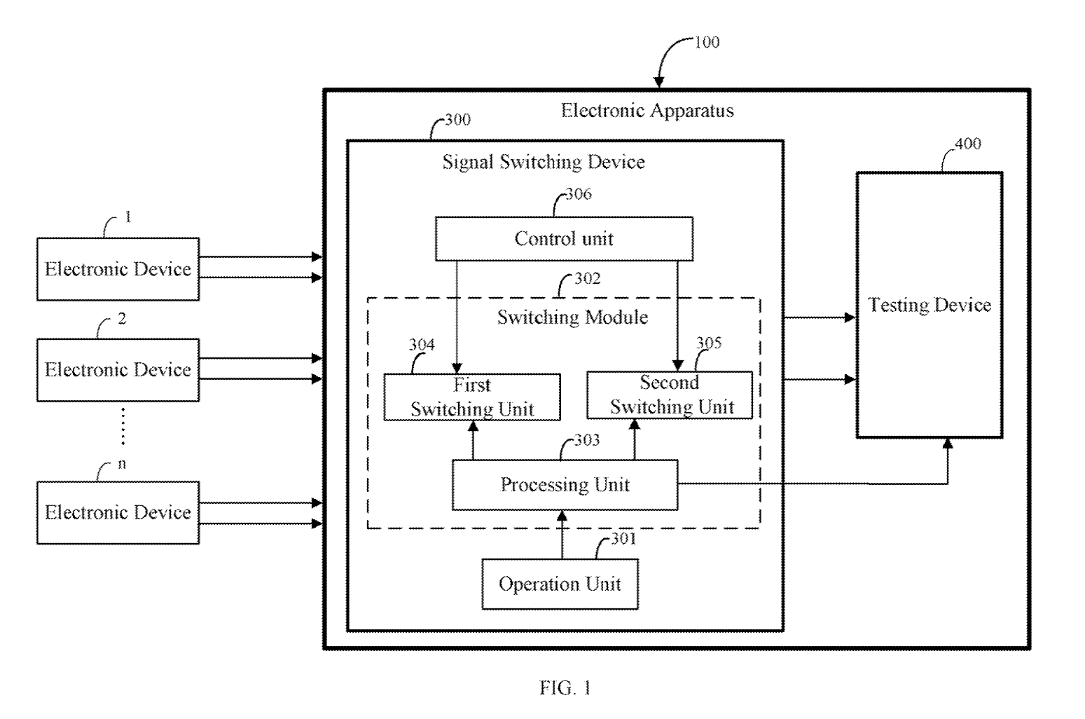

FIG. 1 is an electronic apparatus 100 of one embodiment of the disclosure. The electronic device 100 includes a signal switching device 300 and a testing device 400. The electronic apparatus 100 is connected to a plurality of electronic devices 1, 2 . . . n. The signal switching device 300 is connected between the electronic devices 1, 2 . . . n and the testing device 400. In the embodiment, each electronic device 1, 2 . . . n is a digital versatile disc (DVD) player, and the testing device 400 is a television.

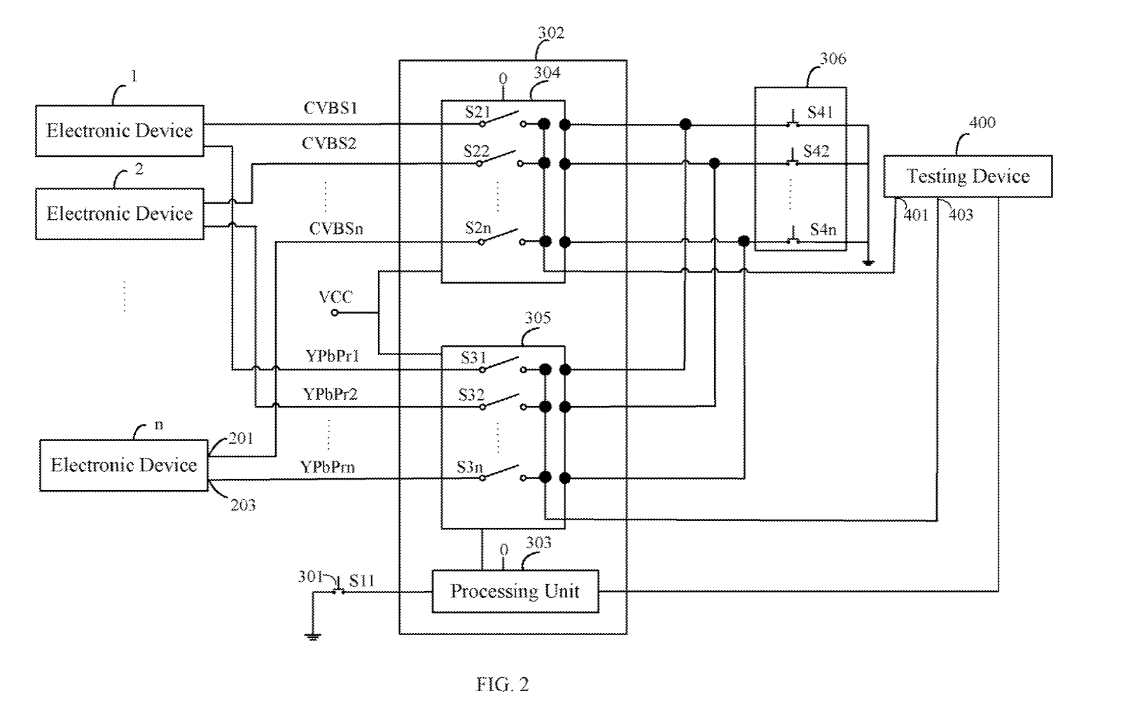

FIG. 2 shows that each electronic device 1, 2 . . . n includes a first output terminal 201 and a second output terminal 203 different from the first output terminal 201. The first output terminal 201 is used for outputting a first signal. The second output terminal 203 is used for outputting a second signal. In the embodiment, the first signal is a composite video broadcast signal. The second signal is an YPbPr signal.

The testing device 400 includes a first input terminal 401 and a second input terminal 403. The first input terminal 401 is used for receiving the first signal of each electronic devices 1, 2 . . . n. The second input terminal 403 is used for receiving the second signal of each electronic devices 1, 2 . . . n.

The signal switching device 300 includes an operation unit 301, a switching module 302 and a control unit 306. The switching module 302 is connected to the operation unit 301 and the control unit 306, and is capable of being switched to a first state and a second state in response to user's operation on the operation unit 301.

When the switching module 302 is in the first state, the switching module 302 receives the first signal from each electronic device 1, 2 . . . n, the control unit 306 controls the switching module 302 to transmit the first signal of each electronic device 1, 2 . . . n to the testing device 400 and controls the testing device 400 to test the first signal of each electronic device 1, 2 . . . n in response to user's operation. When the switching module 302 is in a second state, the switching module 302 receives the second signal from each electronic device 1, 2 . . . n, the control unit 306 controls the switching module 302 to transmit the second signal of each electronic device 1, 2 . . . n to the testing device 400 and controls the testing device 400 to test the second signal of each electronic device 1, 2 . . . n in response to user's operation.

The switching module 302 includes a processing unit 303, a first switching unit 304 and a second switching unit 305. The processing unit 303 is connected to the operation unit 301 for controlling the first switching unit 304 and the second switching unit 305.

The operation unit 301 includes a first switch S11. One end of the first switch S11 is connected to the processing unit 303, and the other end of the first switch S11 is grounded. In the embodiment, the first switch S11 is a press switch.

When the user presses the first switch S11 for a first time, the signal switching device 300 switches to the first state. The processing unit 303 controls the first switching unit 304 to receive the first signal from the electronic devices 1, 2 . . . n, and further controls the second switching unit 305 to stop receiving the second signal from the electronic devices 1, 2 . . . n. Furthermore, the processing unit 303 controls the testing device 400 to switch to a first display interface for displaying the first signal.

When the user presses the first switch S11 for a second time, the signal switching device 300 switches to the second state. The processing unit 303 controls the second switching unit 305 to receive the second signal from the electronic devices 1, 2 . . . n, and further controls the first switching unit 304 to stop receiving the first signal from the electronic devices 1, 2 . . . n. Furthermore, the processing unit 303 controls the testing device to switch to a second display interface for displaying the second signal.

The first switching unit 304 is electrically connected between the first output terminals 201 of the electronic devices 1, 2 . . . n and the control unit 306. The first switching unit 304 is further electrically connected to the first input terminal 401 of the testing device 400.

The first switching unit 304 includes a plurality of second switches S21, S22 . . . S2n. The second switches S21, S22 . . . S2n and the electronic devices 1, 2 . . . n are a one-to-one relationship. One end of each second switch S21, S22 . . . S2n is connected to the first output terminal 201 of the corresponding electronic device 1, 2 . . . n, and the other end of each second switch S21, S22 . . . S2n is connected to the first input terminal 401 of the testing device 400.

The second switching unit 305 is electrically connected between the second output terminals 203 of the electronic devices 1, 2 . . . n and the second control unit 306. The second switching unit 305 is further connected to the second input terminal 403 of the testing device 400.

The second switching unit 305 includes a plurality of third switches S31, S32 . . . S3n. The third switches S31, S32 . . . S3n and the electronic devices 1, 2 . . . n are a one-to-one relationship. One end of each third switch S31, S32 . . . S3n is connected to the second output terminal 203 of the corresponding electronic device 1, 2 . . . n, and the other end of each third switch S31, S32 . . . S3n is connected to the second input terminal 403 of the testing device 400.

The control unit 306 includes a plurality of fourth switches S41, S42 . . . S4n. The fourth switches S41, S42 . . . S4n and the second switches S21, S22 . . . S2n are a one-to-one relationship, and the fourth switches S41, S42 . . . S4n and the third switches S31, S32 . . . S3n also are a one-to-one relationship. One end of each fourth switch S41, S42 . . . S4n is connected to the corresponding second switch S21, S22 . . . S2n and the corresponding third switch S31, S32 . . . S3n, and the other end of each fourth switch S41, S42 . . . S4n is grounded.

When the switching device 300 is in the first state and the user applies a first operation to the fourth switch S41, the second switch S21 is turned on and transmits the first signal of the electronic device 1 to the first input terminal 401. When the user applies the first operation to the fourth switch S42, the second switch S22 is turned on and transmits the first signal of the electronic device 2 to the first input terminal 401. The operation on the fourth switches S43, S44 . . . S4n is similar to the operation of the fourth switches S41, S42, and description about the fourth switches S43, S44 . . . S4n is omitted.

When the switching device 300 is in the second state and the user applies a second operation to the fourth switch S41, the third switch S31 is turned on and transmits the second signal of the electronic device 1 to the second input terminal 403. When the user applies the second operation to the fourth switch S42, the third switch S32 is turned on and transmits the second signal of the electronic device 2 to the second input terminal 403. The operation on the fourth switches S43, S44 . . . S4n is similar to the operation of the fourth switches S41, S42, and description about the fourth switches S43, S44 . . . S4n is omitted.

The principle of the electronic apparatus is illustrated as follows:

When the first switch S11 is pressed for a first time, the first switch S11 transmits a logic low level voltage signal to the processing unit 303. The processing unit 303 controls the first switching unit 304 to receive the first signal of the electronic devices 1, 2 . . . n, and further controls the second switching unit 305 to stop receiving the second signal of the electronic devices 1, 2 . . . n. At the same time, the processing unit 303 controls the testing device 400 to switch to the first display interface for displaying the first signal.

When the user applies the first operation to the fourth switch S41, the second switch S21 turns on for transmitting the first signal of the electronic device 1 to the testing device 400. When the user applies the first operation to the fourth switch S42, the second switch S22 turns on for transmitting the first signal of the electronic device 2 to the testing device 400. The principle of the operation on the fourth switches S43, S44 . . . S4n is similar to the operation of the fourth switches S41, S42, and description on the fourth switches S43, S44 . . . S4n is omitted.

When the first switch S11 is pressed for a second time, the first switch S11 transmits a logic low level voltage signal to the processing unit 303. The processing unit 303 controls the first switching unit 304 to stop receiving the first signal of the electronic devices 1, 2 . . . n, and further controls the second switching unit 305 to receive the second signal of the electronic devices 1, 2 . . . n. At the same time, the processing unit 303 controls the testing device 400 switches to the second display interface for displaying the second signal.

When the user applies the second operation to the fourth switch S41, the third switch S31 turns on for transmitting the second signal of the electronic device 1 to the testing device 400. When the user applies the second operation to the fourth switch S42, the third switch S32 turns on for transmitting the second signal of the electronic device 2 to the testing device 400. The principle of the operation on the fourth switches S43, S44 . . . S4n is similar to the operation of the fourth switches S41, S42, and description on the fourth switches S43, S44 . . . S4n is omitted.

In use, the operator firstly presses the first switch S11 for allowing the first and/or second signal of the electronic devices 1, 2 . . . n to be transmitted to the corresponding first switching unit 304 and/or 305. Simultaneously, the testing device 400 switches to the first display interface for displaying the first and/or second signal. And then, the operator presses one of the fourth switches S41, S42 . . . S4n, so that one of the electronic devices 1, 2 . . . n corresponding to the fourth switch which is connected to the testing device 400. Thus, the first and/or second signal of the electronic devices 1, 2 . . . n is transmitted to the testing device 400.

In other embodiments, the numbers of the electronic device may be one (hereinafter the electronic device 1). Correspondingly, the first switching unit 304 includes a second switch (hereafter the second switch S21), the second switching unit 305 includes a third switch (hereinafter the third switch S31), and the control unit 306 includes a fourth switch (hereafter the fourth switch S41).

The second switch S21 is connected to the first output terminal 201 of the electronic device 1 and the first input terminal 401 of the testing device 400. The third switch S31 is connected to the second output terminal 203 of the electronic device 1 and the second input terminal 403 of the testing device 400. One end of the fourth switch S41 is connected to the second switch S21 and the third switch S31, and the other end of the fourth switch S41 is grounded.

When the first switch S11 is pressed for a first time, the first switch S11 transmits a logic low level voltage signal to the processing unit 303. The processing unit 303 controls the first switching unit 304 to receive the first signal of the electronic device 1 and further controls the second switching unit 305 to stop receiving the second signal of the electronic device 1. At the same time, the processing unit 303 controls the testing device 400 to switch to the first display interface for displaying the first signal. When the user applies the first operation to the fourth switch S41, the second switch S21 turns on for transmitting the first signal of the electronic device 1 to the testing device 400.

When the first switch S11 is pressed for a second time, the first switch S11 transmits a logic low level voltage signal to the processing unit 303. The processing unit 303 controls the first switching unit 304 to stop receiving the first signal of the electronic device 1 and further controls the second switching unit 305 to receive the second signal of the electronic device 1. At the same time, the processing unit 303 controls the testing device 400 to switch to the second display interface for displaying the second signal. When the user applies the second operation to the fourth switch S41, the third switch S31 turns on for transmitting the second signal of the electronic device 1 to the testing device 400.

Although information and the advantages of the present embodiments have been set forth in the foregoing description, together with details of the structures and functions of the present embodiments, the disclosure is illustrative only; changes may be made in detail, especially in the matters of shape, size, and arrangement of parts within the principles of the present embodiments to the full extent indicated by the broad general meaning of the terms in which the appended claims are expressed.

What is claimed is:

1. A signal switching device connected to at least one electronic device and a testing device, each electronic device outputting a first signal and a second signal different from the first signal, the signal switching device comprising:
a switching module connected to the at least one electronic device and capable of being switched between a first state and a second state; and
a control unit connected to the switching module;
wherein when the switching module is in the first state, the switching module receives the first signal from each electronic device, the control unit controls the switching module to transmit the first signal of each electronic device to the testing device and controls the testing device to test the first signal of each electronic device in response to user's operation; when the switching module is in a second state, the switching module receives the second signal from each electronic device, the control unit controls the switching module to transmit the second signal of each electronic device to the testing device and controls the testing device to test the second signal of each electronic device in response to user's operation.

2. The signal switching device of claim 1, wherein when the switching module is in the first state, the switching module stops to receive the second signal from at least one electronic device; when the switching module is in the second state, the switching module stops to receive the first signal from the at least one electronic device.

3. The signal switching device of claim 1, further comprising an operation unit, wherein the operation unit controls the switching module to be switched between the first state and the second state in response to user's operation, the operation unit comprises a first switch, one end of the first switch is connected to the switching module, and the other end of the first switch is grounded; when the first switch is pressed for a first time, the switching module is switched to the first state; when the first switch is pressed for a second time, the switching module is switched to the second state.

4. The signal switching device of claim 1, wherein the switching module comprises a first switching unit, a second switching unit and a processing unit, when the switching module is in the first state, the processing unit controls the first switching unit to receive the first signal from each electronic device and controls the second switching unit to stop receiving the second signal from each electronic device; when the switching module is in the second state, the processing unit controls the second switching unit to receive the second signal from each electronic device and control the first switching unit to stop receiving the first signal from each electronic device.

5. The signal switching device of claim 4, wherein each electronic device comprises a first output terminal for outputting the first signal and a second output terminal for outputting the second signal; the first switching unit is connected to the first output terminal of each electronic device for receiving the first signal, and the second switching unit is connected to the second output terminal of each electronic for receiving the second signal.

6. The signal switching device of claim 5, wherein the first switching unit comprises at least one second switch, one end of each second switch is connected to the first output terminal of each electronic device, and the other end of each second switch is connected to the control unit and the testing device; the control unit comprises at least fourth switch, one end of each fourth switch is connected to each second switch, and the other end of each fourth switch is grounded.

7. The signal switching device of claim 6, wherein the second switching unit comprises at least one third switch; one end of each third switch is connected to the second output terminal of each electronic device, and the other end of each third switch is connected to the control unit and the testing device; one end of each fourth switch is connected to each third switch, and the other end of each fourth switch is grounded.

8. The signal switching device of claim 7, wherein when the switching module is in the first state and the user applies a first operation on each fourth switch, the corresponding second switch is turned on to transmit the first signal of the corresponding electronic device to the testing device; when the switching module is in the second state and the user applies a second operation on each fourth switch, the corresponding third switch is turned on to transmit the second signal of the corresponding electronic device to the testing device.

9. The signal switching device of claim 1, wherein the control unit selectable controls the testing device to be switched to a first display interface for displaying the first signal and a second display interface for displaying the second signal in response to user's operation.

10. An electronic apparatus electrically connected to at least one electronic device, each electronic device outputting a first signal and a second signal different from the first signal, the electronic apparatus comprising:
a testing device; and
a signal switching device connected between at least one electronic device and the testing device;
the signal switching device comprising:
a switching module connected to at least one electronic device and capable of being switched between a first state and a second state; and
a control unit connected to the switching module;
wherein when the switching module is in the first state, the switching module receives the first signal from each electronic device, the control unit controls the switching module to transmit the first signal of each electronic device to the testing device and controls the testing device to test the first signal of each electronic device in response to user's operation; when the switching module is in a second state, the switching module receives the second signal from each electronic device, the control unit controls the switching module to transmit the second signal of each electronic device to the testing device and controls the testing device to test the second signal of each electronic device in response to user's operation.

11. The electronic apparatus of claim 10, wherein when the switching module is in the first state, the switching module stops receiving the second signal from at least one electronic device; when the switching module is in the second state, the switching module stops receiving the first signal from at least one electronic device.

12. The electronic apparatus of claim 10, wherein the signal switching device comprises an operation unit for controlling the switching module to be switched between the first state and the second state in response to user's operation, the operation unit comprises a first switch, one end of the first switch is connected to the switching module, and the other end of the first switch is grounded; when the first switch is pressed for a first time, the switching module is switched to the first state; when the first switch is pressed for a second time, the switching module is switched to the second state.

13. The electronic apparatus of claim 10, wherein the switching module comprises a first switching unit, a second switching unit and a processing unit, when the switching module is in the first state, the processing unit controls the first switching unit to receive the first signal from each electronic device and controls the second switching unit to stop receiving the second signal from each electronic device; when the switching module is in the second state, the processing unit controls the second switching unit to receive the second signal from each electronic device and control the first switching unit to stop receiving the first signal from each electronic device.

14. The electronic apparatus of claim 13, wherein each electronic device comprises a first output terminal for outputting the first signal and a second output terminal for outputting the second signal; the first switching unit is connected to the first output terminal of each electronic device for receiving the first signal, and the second switching unit is connected to the second output terminal of each electronic device for receiving the second signal.

15. The electronic apparatus of claim 14, wherein the first switching unit comprises at least one second switch, one end of each second switch is connected to the first output terminal, and the other end of each second switch is connected to the control unit and the testing device; the control unit comprises at least one fourth switch, one end of each fourth switch is connected to each second switch, and the other end of each fourth switch is grounded; when the switching module is in the first state and the user applies a first operation on each fourth switch, the corresponding switch turns on for transmitting the first signal of the corresponding electronic device to the testing device.

16. The electronic apparatus of claim 15, wherein the second switching unit comprises at least one third switch, one end of each third switch is connected to the second output terminal, and the other end of each third switch is connected to the control unit and the testing device; one end of each fourth switch is connected to each third switch, and the other end of each fourth switch is grounded; when the switching module is in the second state and the user applies a second operation on each fourth switch, the corresponding third switch turns on for transmitting the second signal of the corresponding electronic device to the testing device.

17. A signal switching device connected to a plurality of electronic devices and a testing device, each electronic device outputting a first signal and a second signal different from the first signal, the signal switching device comprising:
a switching module connected to the electronic devices and capable of being switched between a first state and a second state; and
a control unit connected to the switching module;
wherein when the switching module is in the first state, the switching module receives the first signals from the plurality of electronic devices, the control unit controls the switching module to select one of the first signals and transmit the selected first signal to the testing device, and the control unit further controls the testing device to test the selected first signal in response to user's operation; when the switching module is in a second state, the switching module receives the second signals from the electronic devices, the control unit controls the switching module to select one of the second signal and transmit the selected second signal to the testing device, the control unit further controls the testing device to test the selected second signal in response to user's operation.

18. The signal switching device of claim 17, wherein the switching module comprises a first switching unit, a second switching unit and a processing unit, when the switching module is in the first state, the processing unit controls the first switching unit to receive the first signal from each electronic device and controls the second switching unit to stop receiving the second signal from each electronic device; when the switching module is in the second state, the processing unit controls the second switching unit to receive the second signal from each electronic device and control the first switching unit to stop receiving the first signal from each electronic device.

19. The signal switching device of claim 18, wherein the first switching unit comprises a plurality of second switches corresponding to the electronic devices, the second switching unit comprises a plurality of third switches corresponding to the electronic devices, and the control unit comprises a plurality of fourth switches corresponding to the electronic devices; each second switch is connected to each electronic device and the testing device for transmitting the first signal from the corresponding electronic device to the testing device, each third switch is connected to each electronic device and the testing device for transmitting the second signal from the corresponding electronic device to the testing device, and one end of each fourth switch is connected to each second switch and each third switch, and the other end of each fourth switch is grounded.

20. The signal switching device of claim 19, wherein when the switching module is in the first state and the user applies a first operation on one of the fourth switches, the corresponding second switch is turned on to transmit the first signal of the corresponding electronic device to the testing device; when the switching module is in the second state and the user applies a second operation on each fourth switch, the corresponding third switch is turned on to transmit the second signal of the corresponding electronic device to the testing device.
